(19) United States
(12) Patent Application Publication
(10) Pub. No.: US 2012/0319115 A1
(43) Pub. Date: Dec. 20, 2012

(54) ORGANIC LIGHT-EMITTING DISPLAY DEVICE

(76) Inventors: June-Woo Lee, Yongin-city (KR); Sang-Ho Moon, Yongin-city (KR)

(21) Appl. No.: 13/244,379

(22) Filed: Sep. 24, 2011

(30) Foreign Application Priority Data
Jun. 17, 2011 (KR) 10-2011-0059169

(51) Int. Cl. H01L 51/10

(52) U.S. Cl. 257/59; 257/40; 257/E51.006

(57) ABSTRACT

An organic light-emitting display device including a substrate; a thin film transistor on the substrate, the thin film transistor including an active layer, a gate electrode, and source and drain electrodes that are electrically connected to the active layer; a first resonance layer at the same layer level as the gate electrode; a second resonance layer on the first resonance layer, the second resonance layer being at the same layer level as the source and drain electrodes, and electrically connected to the source and drain electrodes; an insulating layer between the second resonance layer and the first resonance layer; an intermediate layer on the second resonance layer, the intermediate layer including a light-emitting layer; and an opposite electrode on the intermediate layer.

### CROSS-REFERENCE TO RELATED PATENT APPLICATION

This application claims priority to and the benefit of Korean Patent Application No. 10-2011-0059169, filed on Jun. 17, 2011, in the Korean Intellectual Property Office, the disclosure of which is incorporated herein in its entirety by reference.

### BACKGROUND

1. Field

Aspects of embodiments according to the present invention relate to an organic light-emitting display device.

2. Description of the Related Art

Due to a wide viewing angle, a fast response speed, and a low power consumption as well as reduced weight and size, organic light-emitting display devices are regarded as next-generation display devices.

An organic light-emitting display device for realizing full color display uses an optical resonance structure for varying an optical length of each wavelength of light emitted from an organic emission layer of each of the different pixels such as red, green, and blue pixels.

### SUMMARY

Embodiments of the present invention are directed toward an organic light-emitting display device having an improved resonance effect and productivity.

According to an embodiment of the present invention, there is provided an organic light-emitting display device including a substrate; a thin film transistor on the substrate, the thin film transistor including an active layer, a gate electrode, and source and drain electrodes that are electrically connected to the active layer; a first resonance layer at the same layer level as the gate electrode; a second resonance layer on the first resonance layer, the second resonance layer being at the same layer level as the source and drain electrodes, and electrically connected to the source and drain electrodes; an insulating layer between the second resonance layer and the first resonance layer; an intermediate layer on the second resonance layer, the intermediate layer including a light-emitting layer; and an opposite electrode on the intermediate layer.

The second resonance layer may include a semi-transmissive metal.

The semi-transmissive metal may include at least one selected from the group consisting of silver (Ag), an Ag alloy, aluminum (Al), and an Al alloy.

The second resonance layer may have a thickness of 300 Å or less.

The thin film transistor may include a first insulating layer covering the active layer, a gate electrode on the first insulating layer, a second insulating layer covering the gate electrode, and source and drain electrodes on the second insulating layer.

The first resonance layer may have a greater refractive index than that of the insulating layer.

The first resonance layer may include a transparent conductive material.

The transparent conductive material may include at least one selected from the group consisting of indium tin oxide (ITO), indium zinc oxide (IZO), zinc oxide (ZnO), indium oxide (In₂O₃), indium gallium oxide (IGO), and aluminum zinc oxide (AZO).

The first resonance layer may include a metal oxide with a high refractive index.

The metal oxide may include at least one selected from the group consisting of titanium oxide (TiO₂), niobium oxide (Nb₂O₅), tantalum oxide (Ta₂O₅), and aluminum oxide (Al₂O₃).

The first resonance layer may include a semi-transmissive metal.

The semi-transmissive metal may include at least one selected from the group consisting of silver (Ag), an Ag alloy, aluminum (Al), and an Al alloy.

The first resonance layer may have a thickness of 300 Å or less.

The opposite electrode may be a reflective electrode.

According to another embodiment of the present invention, there is provided an organic light-emitting display device including a plurality of pixels on a substrate; a thin film transistor including an active layer, a gate electrode, and source and drain electrodes that are electrically connected to the active layer; a first resonance layer at the same layer level as the gate electrode; a second resonance layer on the first resonance layer, the second resonance layer being at the same layer level as the source and drain electrodes, and electrically connected to the source and drain electrodes; an insulating layer between the second resonance layer and the first resonance layer; an intermediate layer on the second resonance layer, the intermediate layer including a light-emitting layer; and an opposite electrode on the intermediate layer. At least one pixel among the pixels has a resonance distance between the opposite electrode and the second resonance layer that is different from the others of the pixels.

The resonance distance may be adjusted by a thickness of an intermediate layer included in each of the pixels.

The intermediate layer may include at least one selected from the group consisting of a hole injection layer (HIL), a hole transport layer (HTL), an electron injection layer (EIL), and an electron transport layer (ETL).

The resonance distance may be adjusted by a thickness of a light-emitting layer included in each of the pixels.

The second resonance layer may include a semi-transmissive metal.

The opposite electrode may be a reflective electrode.

### BRIEF DESCRIPTION OF THE DRAWINGS

The above and other features and aspects of the present invention will become more apparent by describing in detail exemplary embodiments thereof with reference to the attached drawings in which:

FIG. 1 is a cross-sectional view of a portion of a pixel of an organic light-emitting display device according to an embodiment of the present invention;

FIGS. 2A through 2F are cross-sectional views for describing a method of manufacturing the organic light-emitting display device of FIG. 1, according to an embodiment of the present invention;

FIG. 3 is a cross-sectional view of a portion of a pixel of an organic light-emitting display device according to a Comparative Example;

FIGS. 4A through 4F are cross-sectional views for describing a method of manufacturing the organic light-emitting display device of FIG. 3, according to a Comparative Example;

FIG. 5 is a cross-sectional view of a portion of a pixel of an organic light-emitting display device according to another embodiment of the present invention; and

FIG. 6 is a cross-sectional view of an organic light-emitting display device including a plurality of pixels, according to an embodiment of the present invention.

### DETAILED DESCRIPTION

Hereinafter, the present invention will be described in detail by explaining exemplary embodiments thereof with reference to the attached drawings.

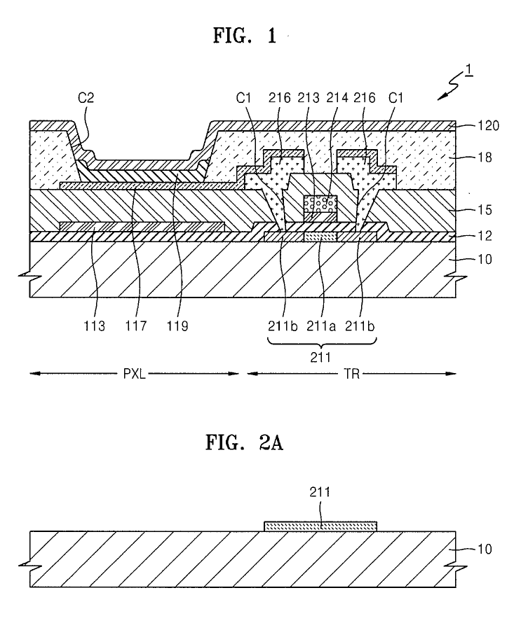

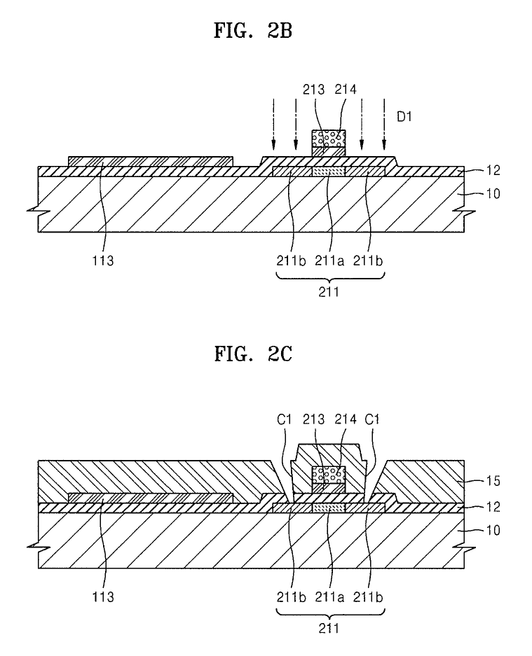

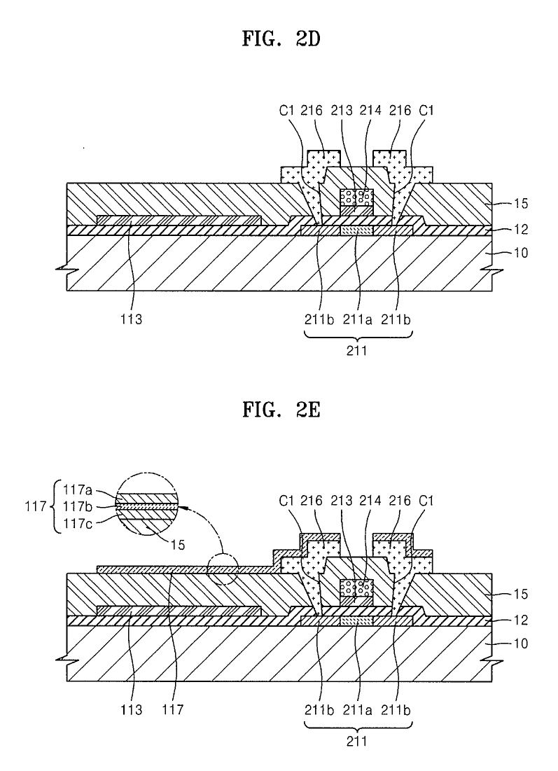

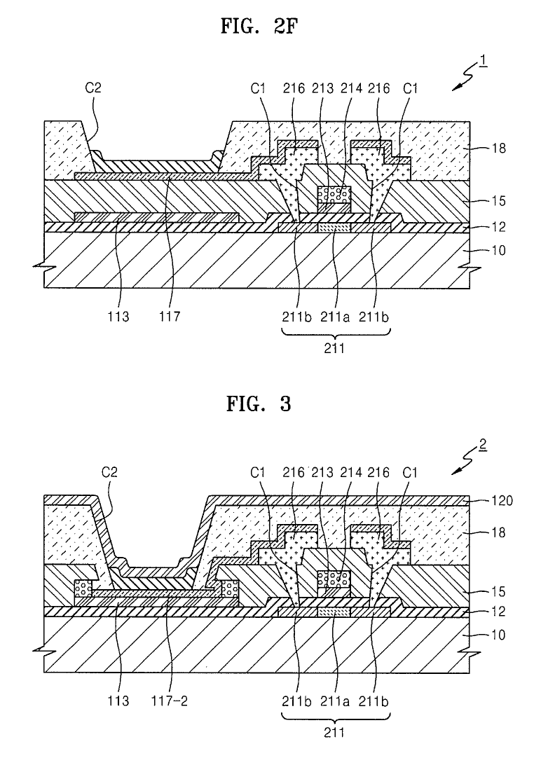

FIG. 1 is a cross-sectional view of a portion of a pixel of an organic light-emitting display device 1 according to an embodiment of the present invention. FIGS. 2A through 2F are cross-sectional views for describing a method of manufacturing the organic light-emitting display device 1 of FIG. 1, according to an embodiment of the present invention.

Referring to FIG. 1, the organic light-emitting display device 1 includes a thin film transistor TR and a pixel unit PXL. The transistor TR includes an active layer 211, first and second gate electrodes 213 and 214, and source and drain electrodes 216. The pixel unit PXL includes a first resonance layer 113, a second resonance layer 117, a light-emitting layer 119, and an opposite electrode 120.

FIG. 2A is a cross-sectional view for describing a first photo mask process of the organic light-emitting display device 1, according to an embodiment of the present invention.

Referring to FIG. 2A, the active layer 211 is disposed on a portion of a substrate 10.

The substrate 10 may be formed of various materials such as a glass material or a plastic material. If the organic light-emitting display device 1 is used in a bottom emission-type light-emitting display apparatus in which an image is realized towards the substrate 10, the substrate 10 may be formed of a transparent material. The active layer 211 may include amorphous silicon or crystalline silicon.

Although not illustrated in FIG. 2A, a smooth surface is formed on the substrate 10, and a buffer layer (not shown) may be formed on the substrate 10 in order to prevent impurities from penetrating into the substrate 10. The butter layer may be formed of SiO₂ and/or SiNx.

FIG. 2B is a cross-sectional view for describing a second photo mask process of the organic light-emitting display device 1, according to an embodiment of the present invention.

Referring to FIG. 2B, a first insulating layer 12 is stacked on the resulting structure of the first photo mask process of FIG. 2A, and the first resonance layer 113 of the pixel unit PXL, and the first gate electrode 213 and the second gate electrode 214 of the thin film transistor TR are sequentially formed on the first insulating layer 12.

The first insulating layer 12 may insulate the active layer 211 from the first and second gate electrodes 213 and 214. The first insulating layer 12 may be formed of an inorganic material such as SiNx and/or SiO₂.

The first and second gate electrodes 213 and 214 may be formed of conductive materials with different etch selectivities. For example, the first and second gate electrodes 213 and 214 may be formed of at least one material selected from the group consisting of a transparent conductive material such as indium tin oxide, titanium (Ti), molybdenum (Mo), aluminum (Al), silver (Ag), copper (Cu), and an alloy thereof that have different etch selectivities.

According to an embodiment of the present embodiment, the first gate electrode 213 is formed of ITO that is a transparent conductive material. The second gate electrode 214 includes three layers of Mo/Al/Mo. The transparent conductive material of the first gate electrode 213 may be selected from the group consisting of ITO, indium zinc oxide (IZO), zinc oxide (ZnO), indium oxide (In₂O₃), indium gallium oxide (IGO), and aluminum zinc oxide (AZO).

The first resonance layer 113 is formed at the same layer level as the first gate electrode 213. According to an embodiment of the present embodiment, the first resonance layer 113 is formed of the same transparent conductive material as that of the first gate electrode 213.

The resulting structure is doped with ion impurities (D1). The ion impurities may include Group III or V ions, and may be doped onto the active layer 211 of the transistor TR as a target with a concentration of 1×10¹⁵ atoms/cm² or more. In this case, the ion impurities may be doped onto the active layer 211 by using the first and second gate electrodes 213 and 214 as a self-aligned mask so that the active layer 211 may include source and drain regions 211b, and a channel region 211a disposed between the source and drain regions 211b.

FIG. 2C is a cross-sectional view for describing a third photo mask process of the organic light-emitting display device 1, according to an embodiment of the present invention.

Referring to FIG. 2C, a second insulating layer 15 is stacked on the resulting structure of the second photo mask process of FIG. 2B, and first contact holes C1 exposing portions of the source and drain regions 211b of the active layer 211 therethrough are formed by patterning the second insulating layer 15.

The second insulating layer 15 serves as an interlevel insulating layer for insulating the first and second gate electrodes 213 and 214 from the source and drain electrodes 216.

In addition, the second insulating layer 15 is formed of a material having a smaller refractive index than that of the first resonance layer 113, thereby maximizing a resonance effect when light emitted from the light-emitting layer 119 is transmitted through the second resonance layer 117, as described below.

The second insulating layer 15 may be formed of various suitable insulating materials. For example, the second insulating layer 15 may be formed of various inorganic materials such as an oxide or a nitride. Examples of an inorganic material for forming the second insulating layer 15 may be SiO₂, SiNx, SiON, Al₂O₃, TiO₂, Ta₂O₅, HfO₂, ZrO₂, BST, PZT, or the like. Also, the second insulating layer 15 may include a material having a smaller refractive index than that of the first resonance layer 113.

FIG. 2D is a cross-sectional view for describing a fourth photo mask process of the organic light-emitting display device 1, according to an embodiment of the present invention.

Referring to FIG. 2D, the source and drain electrodes 216 are formed on the resulting structure of the third photo mask process of FIG. 2C.

The source and drain electrodes 216 respectively contact the source and drain regions 211b of the active layer 211 that are formed through both the second insulating layer 15 and the first insulating layer 12. In FIG. 2D, the source and drain electrodes 216 are formed as a single layer, but the present invention is not limited to this embodiment. That is, the source and drain electrodes 216 may be formed as a plurality of layers, similar to the first gate electrode 213.

FIG. 2E is a cross-sectional view for describing a fifth photo mask process of the organic light-emitting display device 1, according to an embodiment of the present invention.

Referring to FIG. 2E, the second resonance layer 117 that is also a pixel electrode is formed on the source and drain electrodes 216, and extends on the second insulating layer 15. In FIG. 2E, the second resonance layer 117 contacts upper portions of the source and drain electrodes 216, but the present invention is not limited to this embodiment. That is, the second resonance layer 117 may contact any portion of the source and drain electrodes 216.

The second resonance layer 117 includes a semi-transmissive metal. Examples of the semi-transmissive metal may be at least one selected from the group consisting of Ag, an Ag alloy, Cu, and a Cu alloy. The second resonance layer 117 may have a thickness of 300 Å or less so as to serve as a resonance mirror in terms of a relationship with the opposite electrode 120 that is a reflective electrode described below in more detail.

In addition, the second resonance layer 117 may include a single layer, or alternatively, may include a plurality of layers, as shown in FIG. 2E. In particular, when the second resonance layer 117 includes Ag, the second resonance layer 117 may further include a protective layer for protecting the Ag. As shown in FIG. 2E, layers 117a and 117c may be respectively formed on and below a layer 117b including Ag.

FIG. 2F is a cross-sectional view for describing a sixth photo mask process of the organic light-emitting display device 1, according to an embodiment of the present invention.

Referring to FIG. 2F, a third insulating layer 18 is formed on the resulting structure of the fifth photo mask process of FIG. 2E, and an opening C2 exposing an upper surface of the second resonance layer 117 therethrough is formed in the third insulating layer 18.

The third insulating layer 18 may serve as a pixel-defining layer that is formed around the second resonance layer 117 serving as a pixel electrode, and may include an organic insulating material. Examples of the organic insulating material may be a general-purpose polymer (e.g., PMMA, PS), a polymer derivative having a phenol group, an acrylic polymer, an imide-based polymer, an aryl ether-based polymer, an amide-based polymer, a fluorine polymer, a p-xylene-based polymer, a vinyl alcohol-based polymer, and a blend of the above polymers.

Referring back to FIG. 1, the light-emitting layer 119 is disposed in the opening C2, and the opposite electrode 120 that is a common electrode is disposed on the light-emitting layer 119.

The light-emitting layer 119 may be formed of a low-molecular weight organic material or a high-molecular weight organic material. If the light-emitting layer 119 is formed of a low-molecular weight organic material, a hole transport layer (HTL), a hole injection layer (HIL), an electron transport layer (ETL), and an electron injection layer (EIL) may be respectively stacked above and below the light-emitting layer 119. Various other suitable layers may be stacked if necessary. Examples of the low-molecular weight organic material may include copper phthalocyanine (CuPc), N′-Di(naphthalene-1-yl)-N,N′-diphenyl-benzidine (NPB), and tris-8-hydroxyquinoline aluminum (Alq3).

If the light-emitting layer 119 is formed of a high-molecular weight organic material, the organic light-emitting display device 1 may include an HTL as well as the light-emitting layer 119. The HTL may be formed of poly-(2,4)-ethylene-dihydroxy thiophene (PEDOT) or polyaniline (PANI). Examples of the high-molecular weight organic material may include poly-phenylenevinylene (PPV)-based high-molecular weight organic material and polyfluorene-based high-molecular weight organic material.

In the organic light-emitting display device 1, the second resonance layer 117 serves as an anode, and the opposite electrode 120 serves as a cathode. Also, polarities of the second resonance layer 117 and the opposite electrode 120 may be reversed.

The opposite electrode 120 may be a reflective electrode including a reflective material. In this case, the opposite electrode 120 may include at least one selected from the group consisting of Al, Mg, Li, Ca, LiF/Ca, and LiF/Al. Since the opposite electrode 120 is a reflective electrode, light emitted from the light-emitting layer 119 is reflected off the opposite electrode 120, and is emitted toward the substrate 10 through the second resonance layer 117.

The light emitted from the light-emitting layer 119 primarily resonates between the opposite electrode 120 as a reflective electrode and the second resonance layer 117 as a semi-transmissive layer. Light transmitted through the second resonance layer 117 secondarily resonates between the second insulating layer 15 and the first resonance layer 113. The organic light-emitting display device 1 includes dual resonance layers 113 and 117 so as to maximize a resonance effect, thereby increasing light usage efficiency.

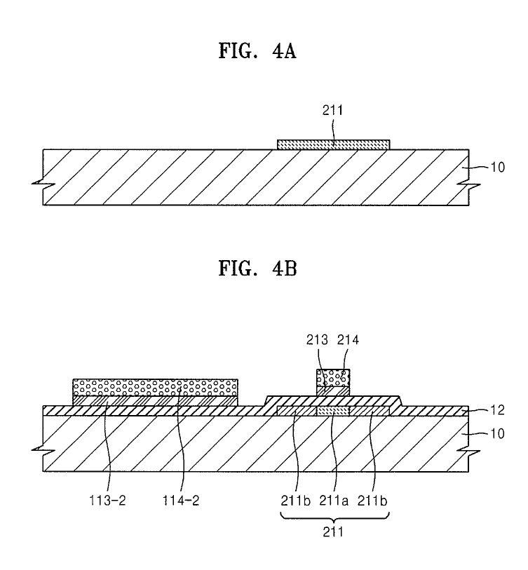

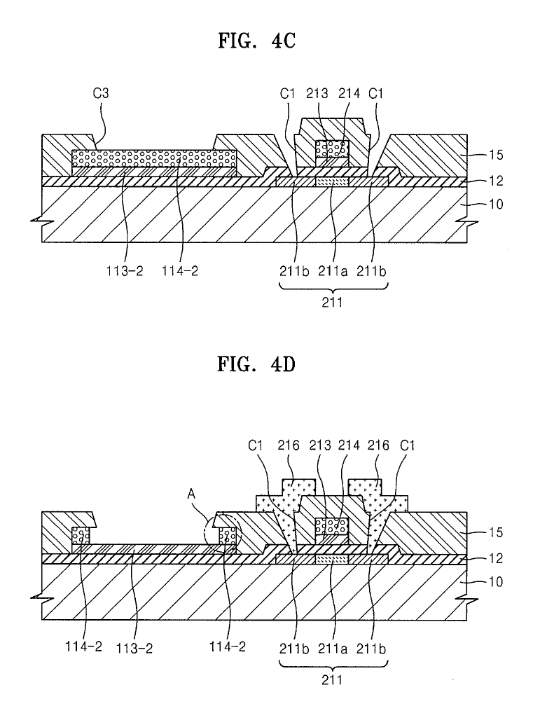

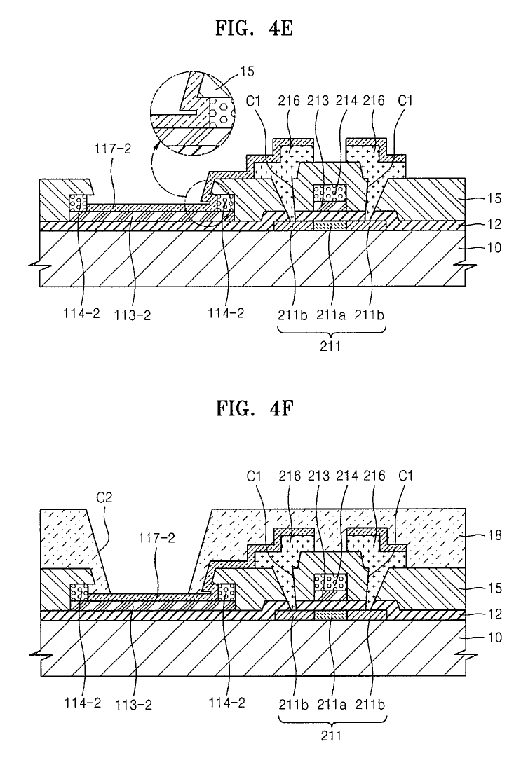

FIG. 3 is a cross-sectional view of a portion of a pixel of an organic light-emitting display device 2 according to a Comparative Example. FIGS. 4A through 4F are cross-sectional views for describing a method of manufacturing the organic light-emitting display device 2 of FIG. 3, according to a Comparative Example.

FIG. 4A is a cross-sectional view for describing a first photo mask process of the organic light-emitting display device 2, according to a Comparative Example.

Referring to FIG. 4A, the active layer 211 is disposed on the substrate 10.

FIG. 4B is a cross-sectional view for describing a second photo mask process of the organic light-emitting display device 2, according to a Comparative Example.

Referring to FIG. 4B, the first insulating layer 12 is stacked on the resulting structure of the first photo mask process of FIG. 4A, and a first pixel electrode 113-2 and a second pixel electrode 114-2 of the pixel unit PXL, and the first gate electrode 213 and the second gate electrode 214 of the thin film transistor TR are sequentially formed on the first insulating layer 12.

FIG. 4C is a cross-sectional view for describing a third photo mask process of the organic light-emitting display device 2, according to a Comparative Example.

Referring to FIG. 4C, the second insulating layer 15 is stacked on the resulting structure of the second photo mask process of FIG. 4B, and by patterning the second insulating layer 15, first contact holes C1 exposing portions of the source and drain regions 211b of the active layer 211 therethrough, and a third contact hole C3 exposing an upper portion of the second pixel electrode 114-2 of the pixel unit PXL, are formed.

FIG. 4D is a cross-sectional view for describing a fourth photo mask process of the organic light-emitting display device 2, according to a Comparative Example.

Referring to FIG. 4D, the source and drain electrodes 216 are formed on the resulting structure of the third photo mask process of FIG. 4C. Materials for forming the source and drain electrodes 216 formed on the third contact holes C3 are concurrently (e.g., simultaneously) etched with the second pixel electrode 114-2. In this case, recesses may be formed in the second insulating layer 15.

FIG. 4E is a cross-sectional view for describing a fifth photo mask process of the organic light-emitting display device 2, according to a Comparative Example.

Referring to FIG. 4E, a second resonance layer 117-2 is formed on the source and drain electrodes 216 and the first pixel electrode 113-2, and extends on the first pixel electrode 113-2 including a semi-transmissive metal. In this case, due to the recess generated on an edge of the first pixel electrode 113-2 on which the second resonance layer 117-2 is formed, the second resonance layer 117-2 may short circuit, thereby causing pixel errors.

FIG. 4F is a cross-sectional view for describing a sixth photo mask process of the organic light-emitting display device 2, according to a Comparative Example.

Referring to FIG. 4F, the third insulating layer 18 is formed on the resulting structure of the fifth photo mask process of FIG. 4E, and the opening C2 exposing an upper surface of the second resonance layer 117-2 therethrough is formed in the third insulating layer 18.

Referring to FIG. 3, the light-emitting layer 119 is disposed in the opening C2, and the opposite electrode 120 that is a common electrode is disposed on the light-emitting layer 119.

In the organic light-emitting display device 2 according to a Comparative Example, due to the recess generated on the edge of the first pixel electrode 113-2, the second resonance layer 117-2 may short circuit to cause pixel errors. However, according to the present embodiment of the present invention, the organic light-emitting display device 1 may avoid the above-described problem. Thus, product failure may be reduced, and productivity may be increased.

The organic light-emitting display device 2 according to a Comparative Example includes the first pixel electrode 113-2 as a transparent conductive layer that is disposed just below the second resonance layer 117-2, and thus the Comparative Example may not obtain a resonance effect. That is different from the organic light-emitting display device 1 according to the embodiment of the present invention in which a resonance effect is realized due to a refractive index difference between the first resonance layer 113 and the second insulating layer 15.

In the above-described embodiment of the present invention, the first resonance layer 113 is formed of a transparent conductive material, but the present invention is not limited to this embodiment. That is, the first resonance layer 113 may not be formed of a conductive material as long as a material for forming the first resonance layer 113 has a greater refractive index than that of the second insulating layer 15. For example, the first resonance layer 113 may include a metal oxide with a high refractive index. That metal oxide may be at least one selected from the group consisting of titanium oxide (TiO₂), niobium oxide (Nb₂O₅), tantalum oxide (Ta₂O₅), and aluminum oxide (Al₂O₃).

FIG. 5 is a cross-sectional view of a portion of a pixel of an organic light-emitting display device 3 according to another embodiment of the present invention. The organic light-emitting display device 3 will be described in terms of its differences from the organic light-emitting display device 1.

Referring to FIG. 5, the organic light-emitting display device 3 includes the thin film transistor TR and the pixel unit PXL. The thin film transistor TR includes the active layer 211, and the first and second gate electrodes 213 and 214. The pixel unit PXL includes a first resonance layer 113-3, the second resonance layer 117, the light-emitting layer 119, and the opposite electrode 120.

The organic light-emitting display device 3 is different from the organic light-emitting display device 1 in terms of a structure of the first resonance layer 113-3. The first resonance layer 113-3 may be formed of a semi-transmissive metal, similar to the second resonance layer 117. Thus, the first resonance layer 113-3 may be at least one selected from the group consisting of Ag, an Ag alloy, Al, and an Al alloy.

The first resonance layer 113-3 may have a thickness of 300 Å or less so as to serve as a resonance mirror.

In addition, the first resonance layer 113-3 may include a single layer, or alternatively, may include a plurality of layers, as shown in FIG. 5. In particular, when the first resonance layer 113-3 includes Ag, the first resonance layer 113-3 may further include a protective layer for protecting the Ag. As shown in FIG. 5, layers 113-3a and 113-3c may be formed respectively on and below a layer 113-3b including Ag.

The organic light-emitting display device 1 has a resonance effect due to a refractive index difference between the first resonance layer 113 and the second insulating layer 15, whereas the organic light-emitting display device 3 may have a better resonance effect than the organic light-emitting display device 1 because like the second resonance layer 117, the first resonance layer 113-3 also serves as a resonance mirror.

An organic light-emitting display device having a single pixel is illustrated in the diagrams, but the present invention is not limited to this embodiment. That is, the organic light-emitting display device may include a plurality of pixels.

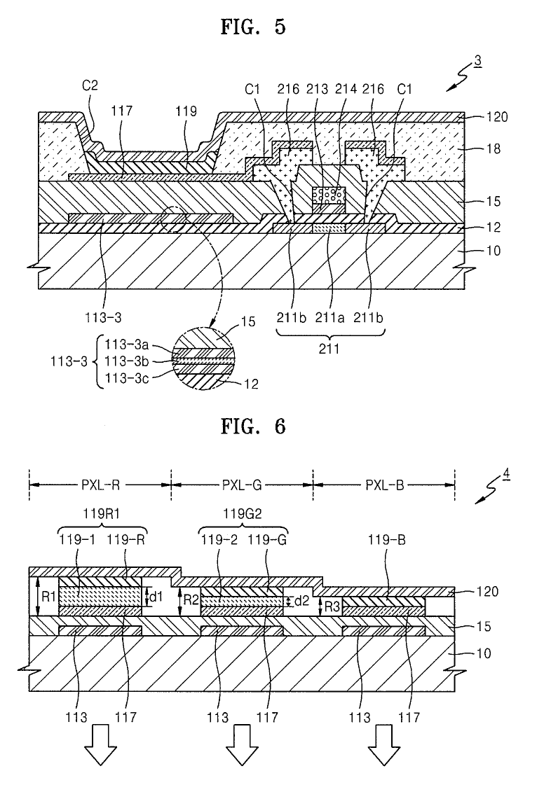

FIG. 6 is a cross-sectional view of an organic light-emitting display device 4 including a plurality of pixels, according to an embodiment of the present invention.

Referring to FIG. 6, a plurality of pixels PXL-R, PXL-G, and PXL-B are formed on the substrate 10.

The first resonance layer 113 and the second resonance layer 117 that is a semi-transmissive mirror are formed to have the same thickness at each of the pixels PXL-R, PXL-G, and PXL-B.

The second insulating layer 15 is disposed between the first resonance layer 113 and the second resonance layer 117. The first resonance layer 113 may be formed of a material having a greater refractive index than that of the second insulating layer 15, and the first resonance layer 113 may be a transparent conductive layer, an insulating layer having a high refractive index, or a semi-transmissive layer.

Intermediate layers 119-R1, 119-G2, and 119-B having different resonance thicknesses R1, R2, and R3 are disposed between the opposite electrode 120 that is a reflective mirror and the second resonance layer 117 that is a semi-transmissive mirror of each of the pixels PXL-R, PXL-G, and PXL-B.

The intermediate layers 119-R1, 119-G2, and 119-B of the pixels PXL-R, PXL-G, and PXL-B include light-emitting layers 119-R, 119-G, and 119-B having the same thickness, respectively, and the intermediate layers 119-R1 and 119-G2 respectively include auxiliary hole transport layers 119-1 and 119-2 having different thicknesses d1 and d2. In FIG. 6, an auxiliary hole transport layer of the blue intermediate layer 119-B is not illustrated, but the present invention is not limited to this embodiment. In other words, the blue intermediate layer 119-B may include an auxiliary hole transport layer having a different thickness from the intermediate layers 119-R1 and 119-G2, and the light-emitting layers 119-R, 119-G, and 119-B may have different thicknesses. Although not illustrated in FIG. 6, an HTL, an HIL, an EIL, an ETL, and the like may be further disposed between the second resonance layer 117 and the opposite electrode 120, and may have different thicknesses so as to have different resonance distances.

The organic light-emitting display device 4 may have different resonance distances for respective pixels, thereby realizing various colors.

According to an organic light-emitting display device according to the embodiments of the present invention, a resonance effect may be maximized or improved by using a dual resonance structure including a first resonance layer and a second resonance layer.

In addition, since the second resonance layer is formed on an insulating layer, short circuiting of a pixel unit is prevented, thereby increasing productivity.

While the present invention has been particularly shown and described with reference to exemplary embodiments thereof, it will be understood by those of ordinary skill in the art that various changes in form and details may be made therein without departing from the spirit and scope of the present invention as defined by the following claims and their equivalents.

What is claimed is:

1. An organic light-emitting display device comprising:
a substrate;
a thin film transistor on the substrate, the thin film transistor comprising an active layer, a gate electrode, and source and drain electrodes electrically connected to the active layer;
a first resonance layer at the same layer level as the gate electrode;
a second resonance layer on the first resonance layer, the second resonance layer being at the same layer level as the source and drain electrodes, and electrically connected to the source and drain electrodes;
an insulating layer between the second resonance layer and the first resonance layer;
an intermediate layer on the second resonance layer, the intermediate layer comprising a light-emitting layer; and
an opposite electrode on the intermediate layer.

2. The organic light-emitting display device of claim 1, wherein the second resonance layer comprises a semi-transmissive metal.

3. The organic light-emitting display device of claim 2, wherein the semi-transmissive metal comprises at least one selected from the group consisting of silver (Ag), an Ag alloy, aluminum (Al), and an Al alloy.

4. The organic light-emitting display device of claim 2, wherein the second resonance layer has a thickness of 300 Å or less.

5. The organic light-emitting display device of claim 1, wherein the thin film transistor comprises:
a first insulating layer covering the active layer, wherein the gate electrode is on the first insulating layer; and
a second insulating layer covering the gate electrode, wherein the source and drain electrodes are on the second insulating layer.

6. The organic light-emitting display device of claim 1, wherein the first resonance layer has a greater refractive index than that of the insulating layer.

7. The organic light-emitting display device of claim 6, wherein the first resonance layer comprises a transparent conductive material.

8. The organic light-emitting display device of claim 7, wherein the transparent conductive material comprises at least one selected from the group consisting of indium tin oxide (ITO), indium zinc oxide (IZO), zinc oxide (ZnO), indium oxide (In₂O₃), indium gallium oxide (IGO), and aluminum zinc oxide (AZO).

9. The organic light-emitting display device of claim 6, wherein the first resonance layer comprises a metal oxide with a high refractive index.

10. The organic light-emitting display device of claim 9, wherein the metal oxide comprises at least one selected from the group consisting of titanium oxide (TiO₂), niobium oxide (Nb₂O₅), tantalum oxide (Ta₂O₅), and aluminum oxide (Al₂O₃).

11. The organic light-emitting display device of claim 1, wherein the first resonance layer comprises a semi-transmissive metal.

12. The organic light-emitting display device of claim 11, wherein the semi-transmissive metal comprises at least one selected from the group consisting of silver (Ag), an Ag alloy, aluminum (Al), and an Al alloy.

13. The organic light-emitting display device of claim 12, wherein the first resonance layer has a thickness of 300 Å or less.

14. The organic light-emitting display device of claim 1, wherein the opposite electrode is a reflective electrode.

15. An organic light-emitting display device comprising:
a substrate;
a plurality of pixels on the substrate;
a thin film transistor comprising an active layer, a gate electrode, and source and drain electrodes electrically connected to the active layer;
a first resonance layer at the same layer level as the gate electrode;
a second resonance layer on the first resonance layer, the second resonance layer being at the same layer level as the source and drain electrodes, and electrically connected to the source and drain electrodes;
an insulating layer between the second resonance layer and the first resonance layer;
an intermediate layer on the second resonance layer, the intermediate layer comprising a light-emitting layer; and
an opposite electrode on the intermediate layer,
wherein at least one pixel among the pixels has a resonance distance between the opposite electrode and the second resonance layer that is different from the others of the pixels.

16. The organic light-emitting display device of claim 15, wherein the resonance distance is adjusted by a thickness of an intermediate layer included in each of the pixels.

17. The organic light-emitting display device of claim 15, wherein the intermediate layer comprises at least one selected from the group consisting of a hole injection layer (HIL), a hole transport layer (HTL), an electron injection layer (EIL), and an electron transport layer (ETL).

18. The organic light-emitting display device of claim 15, wherein the resonance distance is adjusted by a thickness of a light-emitting layer included in each of the pixels.

19. The organic light-emitting display device of claim 15, wherein the second resonance layer comprises a semi-transmissive metal.

20. The organic light-emitting display device of claim 15, wherein the opposite electrode is a reflective electrode.
